(19) United States
(12) Patent Application Publication
(10) Pub. No.: US 2008/0311732 A1
(43) Pub. Date: Dec. 18, 2008

(54) Method for Forming Non-Amorphous, Ultra-Thin Semiconductor Devices Using Sacrificial Implantation Layer

(75) Inventors: Omer Dokumaci, Wappingers Falls, NY (US); Paul Ronsheim, Hopewell Junction, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 10/596,168

(22) PCT Filed: Dec. 4, 2003
(86) PCT No.: PCT/US03/38559

§ 371 Date: Jun. 2, 2006

(51) Int. Cl. H01L 21/425

(52) U.S. Cl. 438/525; 257/E21.345

(57) ABSTRACT

A method for forming a semiconductor device includes defining a sacrificial layer (108) over a single crystalline substrate (106). The sacrificial layer (108) is implanted with a dopant species in a manner that prevents the single crystalline substrate (106) from becoming substantially amorphized. The sacrificial layer (108) is annealed so as to drive said dopant species from said sacrificial layer (108) into said single crystalline substrate (106).

### TECHNICAL FIELD

The present invention relates generally to semiconductor device processing and, more particularly, to a method for forming non-amorphous, ultra-thin semiconductor devices using a sacrificial implantation layer.

### BACKGROUND ART

The formation of ultra-shallow p⁺ and n⁺ doped regions within a silicon substrate is a crucial step in the fabrication of metal-oxide semiconductor (MOS) transistors and other semiconductor devices used within integrated circuits. The ever-decreasing size of MOS transistors requires a down scaling of all lateral and vertical dimensions of the transistor. In conventional scaling scenarios, the depth of the junctions, which form the source and drain regions of MOS transistors, scales linearly with gate length. Therefore, shallower junctions of p⁺ and n⁺ regions which have suitably low sheet resistance are required in the present semiconductor manufacturing industry.

In conventional semiconductor manufacturing processes, shallow junctions may be formed by ion implantation followed by an anneal such as a rapid thermal anneal (RTA). The reliability of this technique is known in the art down to a junction depth of 300 to 400 angstroms (Å). The task of producing a doped region having both a junction depth of less than 300 or 400 Å and a suitably low sheet resistance is more challenging. This task is rendered particularly difficult for p-type shallow doped regions by the implant and diffusion properties of boron, in particular. Significant issues in this regard include control of dopant channeling, reduction of thermal diffusion, and suppression of transient-enhanced diffusion, especially in the case of boron and phosphorus. Moreover, good device performance is only attained with a low sheet resistance of the shallow regions (i.e., with a high impurity concentration). The scaling tendency has been to reduce the ion implant energy while the total dopant level is kept more or less constant, and to reduce the thermal budget without significantly deteriorating the dopant activation level by introducing rapid thermal anneals and spike anneals.

This conventional scaling is expected to become difficult below the 300 to 400 Å junction depths, particularly for p⁺ junctions. The technical difficulty in making a high-current, low-energy ion implantation beam may be alleviated by the use of plasma doping (alternatively called plasma immersion ion implantation). Alternative processes that avoid implantation altogether have also been considered. Examples of such processes include rapid thermal vapor phase doping, gas immersion laser doping, and solid state hot diffusion such as from a BSG (borosilicate glass), PSG (phosphorus silicon glass), or ASG (arsenic silicon glass) film. All of these processes, however, face one or more problems with manufacturability.

In the fabrication of ultra-thin silicon-on-insulator (SOI) devices (e.g., SOI thicknesses<100 Å) or Fin Field Effect Transistors (FinFETs) (e.g., thickness<200 Å), care should also be taken so that the device silicon is not amorphized as a result of the extension and halo implant processes. If the silicon is amorphized down to the bottom of the buried oxide (BOX) region, it then may “regrow” (following anneal) in the form of polycrystalline silicon. In addition, such regrowth could also create stacking faults, thereby possibly shorting the devices.

In conventional thick silicon structures, a high dose implantation is used to produce low-resistance silicon source/drain (S/D) extensions, and the amorphized silicon regrows from the silicon lattice at the amorphization front. However, these same high dose implants directly in ultra-thin silicon structures fully amorphize the silicon layer, resulting in a poor solid-phase regrowth of the epitaxial silicon, as no remaining template exists. Generally, the silicon regrows as polysilicon, or multiple crystal grains rather than one continuous crystal. This polysilicon will have a higher sheet resistance than regrown single crystal silicon, and the device will suffer low Iₒₙ.

One possible approach to preventing complete amorphization involves depositing an undoped oxide on top of the thin SOI, and thereafter implant through the oxide and into the film. However, in eliminating the amorphization in silicon, most of the dopant will remain in the oxide after the implant step. Accordingly, it would be desirable to be able to introduce the desired concentration of dopant into the silicon for extension and halo formation, but without amorphizing the silicon in the process.

### SUMMARY OF INVENTION

The foregoing discussed drawbacks and deficiencies of the prior art are overcome or alleviated by a method for forming a semiconductor device. In an exemplary embodiment, the method includes defining a sacrificial layer over a single crystalline substrate. The sacrificial layer is implanted with a dopant species in a manner that prevents the single crystalline substrate from becoming substantially amorphized. The sacrificial layer is annealed so as to drive said dopant species from said sacrificial layer into said single crystalline substrate.

The present invention has industrial applicability in the area of semiconductor device processing and, in particular, to the formation of ultra-thin semiconductor devices having silicon regions undamaged (non-amorphized) by dopant implant operations.

These and other aspects of the invention are described in further detail below.

### BRIEF DESCRIPTION OF THE DRAWINGS

Referring to the exemplary drawings wherein like elements are numbered alike in the several Figures:

FIGS. 1-11 illustrate cross-sectional views of an exemplary processing sequence of a method for forming non-amorphous, ultra-thin semiconductor devices using a sacrificial implantation layer, in accordance with an embodiment of the invention.

### DETAILED DESCRIPTION OF THE INVENTION

It has recently been found that implanted arsenic (As) within an oxide layer completely diffuses out of the oxide layer with a small thermal anneal budget, regardless of whether the bulk of the dopant concentration is located within the oxide layer following the implant step. A similar phenomenon has also been observed with BF₂ dopant as well. For example, if a 1 keV arsenic implant is applied to a 35 Å layer of oxide on single crystal silicon, there will be no substantial amorphization of the underlying silicon. Moreover, it has been found that nearly all of the arsenic dopant diffuses out of the oxide layer during a subsequent annealing step. Therefore, this technique may be used as the basis for creating low resistance source/drain (S/D) extension junctions without amorphizing silicon.

As is the case with S/D extension formation, a thin SOI device can also be completely amorphized during a halo implant step. This can happen especially during a PFET halo implant, which is usually an arsenic or antimony implant. Arsenic begins to amorphize silicon at a dose of about 1×10¹⁴ atoms/cm², while antimony (Sb) begins to amorphize at about 5×10¹³ atoms/cm². Furthermore, an arsenic halo implant is done at high energies, such as at 50 keV, for example. If the dose exceeds the amorphization threshold, then the depth of the resulting amorphous layer will be about 500 Å, which is unacceptable for thin SOI devices. As the devices are scaled down, the situation becomes worse, since the silicon thickness will be decreased and the halo dose will be increased for future generation technologies.

Thus, in order to prevent amorphization by a halo implant, the same principle of using a sacrificial dopant layer may be applied. That is, a halo implant may be implemented within a thin oxide layer and thereafter diffused out. With this type of implant, however, the degree of implant damage created in the oxide layer may not be sufficient enough to facilitate subsequent dopant diffusion out of the oxide into silicon. Accordingly, a neutral damage creating species (such as Si, Ge or even noble gases, for example) may also be implanted into the oxide to create more damage. Other species that could also be implanted to facilitate more diffusion out of the oxide layer include, but are not limited to, fluorine (F) and indium (In).

Another significant advantage that arises out of diffusing the halo/extension implant out of an oxide layer is that the halo/extension will be sharper. In particular, the halo profile obtained with this method will have a much lower standard deviation as compared to a high-energy implanted halo, since the spread from the implant will be eliminated. This in turn will reduce the short-channel effects and enable further scaling of the devices.

In fully depleted devices (which occur as silicon thickness is reduced below 200-300 Å), the halo profile is fully depleted at nominal channel lengths. Since the amount of depleted charge is dependent on the silicon thickness, the threshold voltage of thin Si devices is sensitive to silicon thickness. This happens because the halo implant places more dose in thicker silicon than in thinner silicon. Furthermore, the variation in silicon thickness across the wafer (especially for a 300 mm wafer) is expected to increase as silicon thins down. Doping from the implanted oxide reduces the threshold sensitivity to silicon thickness, so long as the diffusion distance is less than the minimum silicon thickness.

Therefore, in accordance with an embodiment of the invention, there is disclosed a method for forming non-amorphous, ultra-thin semiconductor devices using a sacrificial implantation layer. More specifically, the present method may be implemented for fabricating low resistance S/D extension regions for ultra-thin semiconductor (e.g., silicon, germanium, etc.) devices. The present method is further useful in provide doping uniformity control for a halo implant, thereby yielding improved voltage threshold (Vₜ) characteristics and short channel effect control.

Briefly stated, after standard gate electrode formation, spacer deposition and etching steps, halo and extension regions for each device is covered with a thin sacrificial material (such as silicon oxide formed by oxidation of the substrate, or other suitable deposited or grown materials). The appropriate regions for doping are then opened in a photoresist mask and a low-energy, shallow ion implantation introduces a controlled dose of dopant into the overlying sacrificial thin film. The photomask is removed and reapplied for the opposite type dopant (n or p). An anneal sequence is then employed to drive the dopant from the sacrificial layer (e.g., oxide) into the semiconductor material. If a halo implant process is desired, it should be done prior to the extension processing. This sequence could then be employed as many times as necessary for the device complexity.

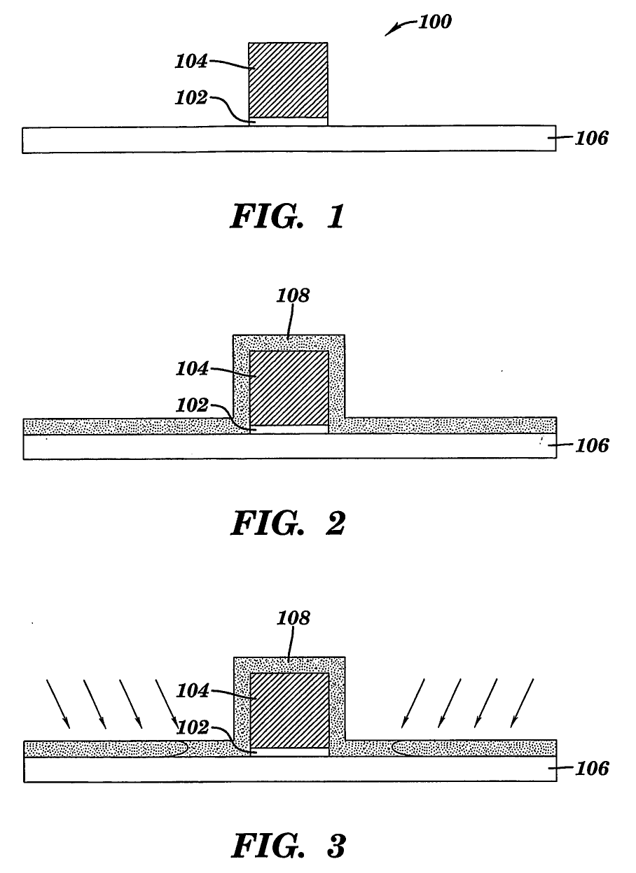

Referring generally now to FIGS. 1-11, there is shown a cross-sectional view of an exemplary processing sequence that utilizes the present methodology. Although the Figures depict the formation of an FET device on a silicon-on-insulator substrate, it will be appreciated that the methodology can also be applied to other types of devices where it is desired to implant a dopant species into a substrate without creating an amorphous region in the crystalline substrate. As shown in FIG. 1, a patterned gate stack 100 comprising gate dielectric 102 and gate 104 is formed on a thin, single crystal structure substrate 106, such as an SOI substrate. Again, however, substrate 106 may be any suitable semiconductor material such as silicon, germanium or a combination thereof, for example. This starting structure may be an SOI device or a FinFET, for example. Then, as shown in FIG. 2, a sacrificial layer 108 is formed over the substrate 106 and gate stack 100.

If the substrate 106 is silicon, the sacrificial layer 108 may include a thin oxide layer grown (or deposited) to an exemplary thickness of about 15-100 Å. In addition to an oxide layer, the sacrificial layer 108 may also be a nitride film, oxynitride film or other dielectric film formed by available mechanisms in the art such as thermal oxidation, chemical vapor deposition (CVD), plasma enhanced CVD (PECVD), and high density plasma (HDP) CVD for example. Regardless of the type of material used, the sacrificial layer material will become a solid-source for diffusion once it is doped with a dopant species by implantation.

FIG. 3 illustrates a halo implant into the sacrificial layer 108. For such an implant, the implantation energy is selected so as to deliver the majority of the dose into the sacrificial layer 108, thus minimizing the dose implanted through the sacrificial layer 108 to prevent crystal damage in the semiconductor substrate 106. The device is initially patterned for either an n-type or p-type implant, and then the pattern is reversed for implantation of the other polarity dopant. The concentration of the dopant dose within the sacrificial layer is graphically represented in FIG. 3 by the curves, which reflect a peak dopant concentration at around the middle of the sacrificial layer thickness.

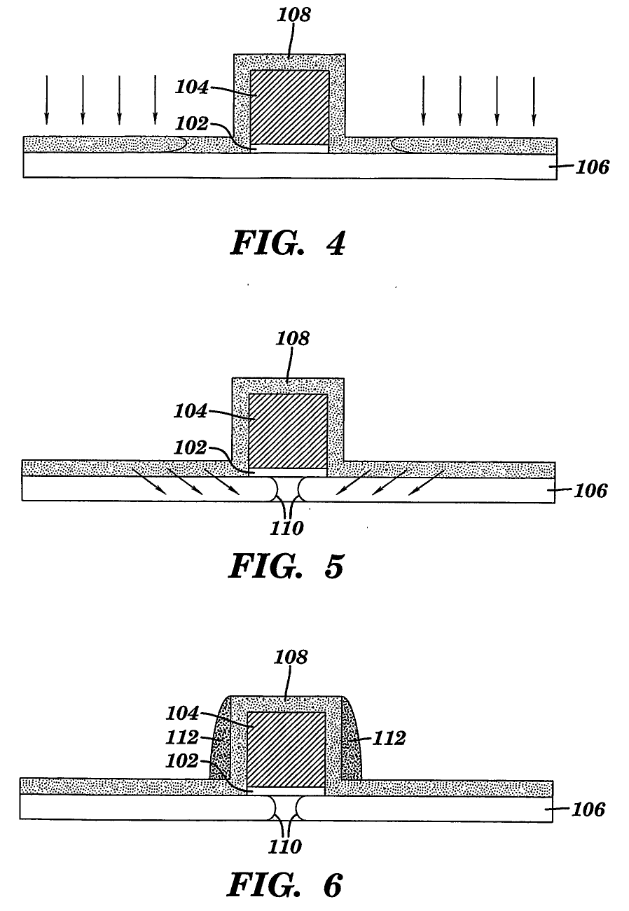

As explained previously, in certain situations the dopant implant dose for a halo implant may not provide sufficient damage to the sacrificial layer 108 (e.g., to an oxide layer). Accordingly, FIG. 4 illustrates an additional implant step, wherein an inert species (such as Si or Ge) is also implanted into the sacrificial layer 108. Then, in FIG. 5, the doped sacrificial layer 108 is annealed so as to facilitate diffusion of the dopant species into the single crystal substrate 106 to create halo regions 110. In order to properly locate the halo regions 110, the annealing step is longer and hotter than for an extension anneal.

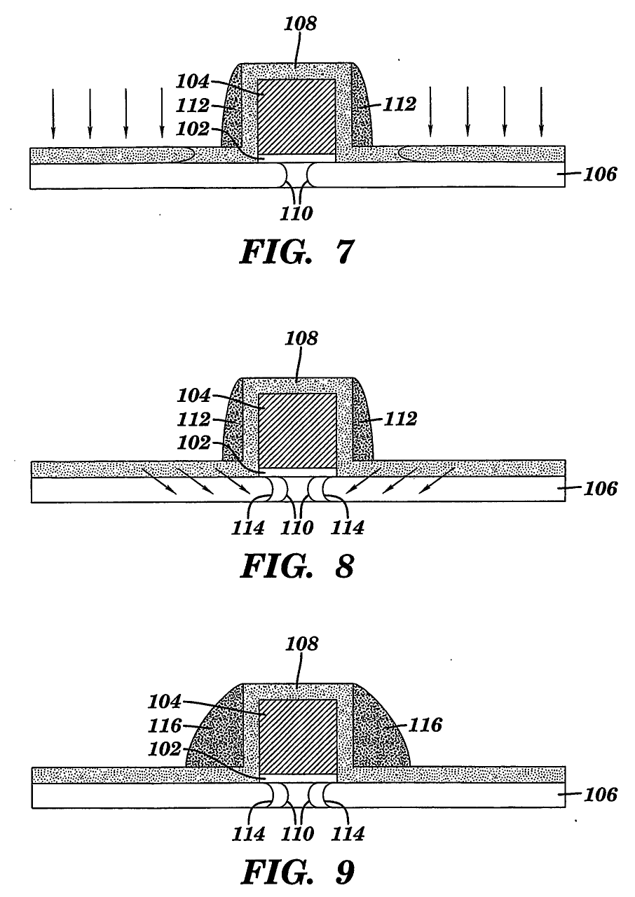

Referring to FIG. 6, there is shown the optional formation of extension spacers 112 that may be used to achieve the appropriate device characteristics of overlap capacitance and resistance. The thickness of the spacers 112 will be determined by device requirements. However, for certain anneal sequences (such as for NFET formation, for example), the spacers may not be needed. In any case, an extension implant is shown in FIG. 7, wherein the same sacrificial layer 108 used for the halo implant diffusion source may also be used for the extension implant. As is the case for the halo implant, the dopant for the extension regions is implanted with an energy appropriate to locate the majority of the dopant dose in the sacrificial layer 108, preferably with less than about 5×10¹⁴ atoms/cm² of dose traveling deeper into the underlying semiconductor material of the substrate 106. A PFET extension implant is masked from the NFET regions, and vice versa, and thus the implant process is done twice to provide both NFET and PFET extensions. Then, as shown in FIG. 8, the extension dopant material is driven into the substrate 106 from the sacrificial layer 108, as represented at 114. A single anneal step can be used to drive both n and p-type extensions.

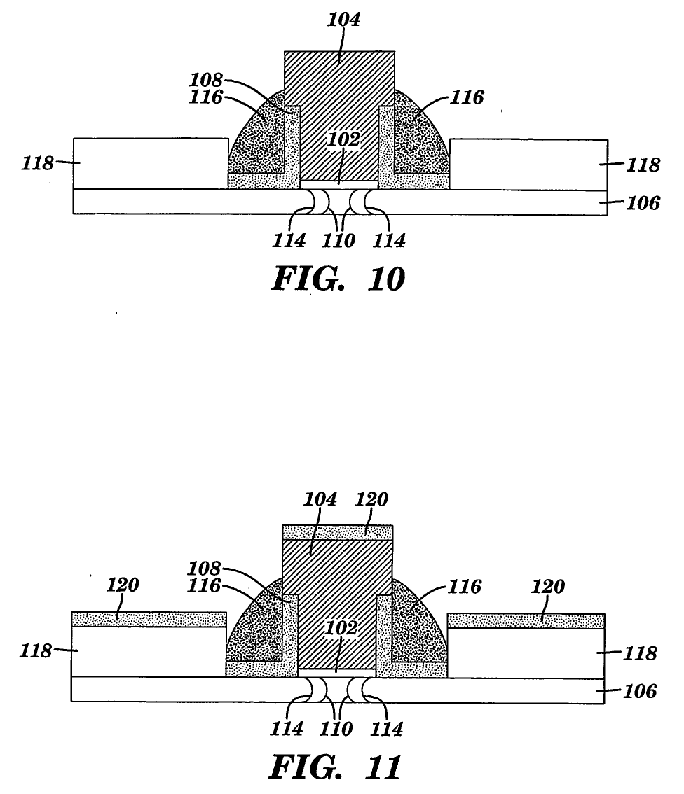

Once the halo and extension implants are completed in a non-amorphous manner, the device fabrication may continue in accordance with conventional processing techniques. In FIG. 9, source/drain spacers 116 (e.g., from a nitride material) are used to separate the source/drain dopants/implants from the gate edge. This maintains device control with the extension and halo doping profiles, while the source/drain regions are maintained for electrical contact. In FIG. 10, exposed portions of the sacrificial layer 108 are removed, and the source/drain regions are thickened with additional silicon (or other semiconductor) material 118 by, for example, selective epitaxial growth. This provides a region for subsequent silicide formation without losing all the previously implanted dopants. The gate 104 may also be thickened with additional doped polysilicon material, as also shown in FIG. 10. Finally, the S/D implants are patterned for NFET and PFET devices, and then annealed before the formation of silicide regions 120.

As will be appreciated, the above described problems of conventional device fabrication in ultra-thin semiconductor architectures (i.e., direct ion implantation into the silicon crystal) have been overcome by the formation of highly doped, low resistance S/D extensions without the deleterious effects of amorphizing implants. When applied to device halo implants, the present method results in more abrupt doping profiles with better short channel effect (SCE) device characteristics than can be obtained with conventional implantation doping. The device operation will also be enhanced by the reduced Vₜ variation within the individual devices of the chip due to the more precise halo shape and resistance.

The use of a thin sacrificial layer (such as an oxide layer), in direct contact with a thin semiconductor layer, to diffuse implanted dopant therein to the semiconductor material below, while similar to diffusion from a solid source such as doped polysilicon or BSG, is much easier to integrate in an existing process. For example, the masking of the implant location is relatively easy for an implant, while relatively hard for a CVD film. Also, the amount of dopant and the depth of the diffusion can be better controlled with the implant dose and the annealing recipe. By removing the amorphous layer in the semiconductor, the material remains crystalline, and will have low resistance when heavily doped by the diffusing species. Without this method, an ultra-thin device material will fully amorphize and regrow as a high resistivity, multi-grained material yielding poor device characteristics (e.g., Iₒₙ/I_{off} ratio).

The halo implant is used to control the device Vₜ and short channel effect. In ultra thin devices, this halo implant can also amorphize the material, resulting in poor resistance and leaky junctions. By using this method of diffusion from the implanted sacrificial layer for halo formation, the dopant profiles will be steeper than in the implanted case, and will have better uniformity, resulting in improved short channel effects. The thickness of the semiconductor layer can vary by large relative amounts due to fabrication difficulties (e.g., ±5 nm in a 20 nm film), which can affect the Vₜ control of the devices. The use of an oxide-diffused halo will provide a shallower halo distribution that is independent of the layer thickness, and thus improve device Vₜ uniformity from layer thickness.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for forming a semiconductor device, the method comprising:
defining a sacrificial layer over a single crystalline substrate;
implanting said sacrificial layer with a dopant species in a manner that prevents said single crystalline substrate from becoming substantially amorphized; and
annealing said sacrificial layer so as to drive said dopant species from said sacrificial layer into said single crystalline substrate.

2. The method of claim 1, wherein said sacrificial layer is a dielectric layer further comprising at least one of: an oxide layer, a nitride layer, and an oxynitride layer.

3. The method of claim 1, further comprising forming a halo implant, wherein, in addition to said dopant species, said sacrificial layer is further implanted with a damage creating species prior to annealing of said sacrificial layer.

4. The method of claim 3, wherein said damage creating species further comprises at least one of: silicon, germanium, indium, fluorine, and a noble gas.

5. The method of claim 3, further comprising forming an extension implant using said sacrificial layer.

6. The method of claim 5, wherein annealing for said halo implant is implemented at a greater temperature and for a longer duration then for said extension implant.

7. The method of claim 1, wherein said sacrificial layer further comprises an oxide layer formed over a silicon substrate, said oxide layer formed at a thickness of about 15 to about 100 angstroms.

8. The method of claim 7, wherein an implantation energy of said dopant species is selected so as to locate a peak concentration of said dopant species at about a middle of said oxide layer.

9. The method of claim 1, wherein said single crystalline substrate further comprises a silicon region of an silicon-on-insulator (SOI) device having a silicon thickness of less than about 100 angstroms.

10. The method of claim 1, wherein said single crystalline substrate further comprises a silicon region of a field effect transistor (FET) device having a thickness of less than about 200 angstroms.

11. The method of claim 1, further comprising:
defining said sacrificial layer over a patterned gate stack formed on said single crystalline substrate;
forming a halo implant by said implanting said sacrificial layer and said annealing said sacrificial layer; and
forming an extension implant by additional implanting and annealing of said sacrificial layer.

12. The method of claim 11, wherein said sacrificial layer is a dielectric layer further comprising at least one of: an oxide layer, a nitride layer, and an oxynitride layer.

13. The method of claim 12, wherein during formation of said halo implant, in addition to said dopant species, said sacrificial layer is further implanted with a damage creating species prior to annealing of said sacrificial layer.

14. The method of claim 13, wherein said damage creating species further comprises at least one of: silicon, germanium, indium, fluorine, and a noble gas.

15. The method of claim 13, wherein annealing for said halo implant is implemented at a greater temperature and for a longer duration then for said extension implant.

16. The method of claim 12, wherein said sacrificial layer further comprises an oxide layer formed over a silicon substrate, said oxide layer formed at a thickness of about 15 to about 100 angstroms.

17. The method of claim 16, wherein an implantation energy of said dopant species is selected so as to locate a peak concentration of said dopant species at about a middle of said oxide layer.

18. The method of claim 11, wherein said single crystalline substrate further comprises a silicon region of an silicon-on-insulator (SOI) device having a silicon thickness of less than about 100 angstroms.

19. The method of claim 11, wherein said single crystalline substrate further comprises a silicon region of a field effect transistor (FET) device having a thickness of less than about 200 angstroms.

20. The method of claim 11, wherein said dopant species comprises at least one of: arsenic (As), phosphorus (P), antimony (Sb), boron (B) and boron fluorine (BF₂).
